(19) United States
(12) Patent Application Publication
(10) Pub. No.: US 2025/0147213 A1
(43) Pub. Date: May 8, 2025

(54) TRANSLUCENT RESIN COMPOSITION, ADHESIVE AGENT, OPTICAL FILM, AND DISPLAY DEVICE

(71) Applicants: YASUHIRO KOIKE, Yokohama-shi (JP); SAIDEN CHEMICAL INDUSTRY CO., LTD., Tokyo (JP)

(72) Inventors: Sumihisa ODA, Saitama-shi (JP); Yasuhiro Koike, Yokohama-shi (JP); Shizuki Sasaki, Kawasaki-shi (JP)

(73) Assignees: YASUHIRO KOIKE, Yokohama-shi (JP); SAIDEN CHEMICAL INDUSTRY CO., LTD., Tokyo (JP)

(21) Appl. No.: 19/018,779

(22) Filed: Jan. 13, 2025

Related U.S. Application Data
(63) Continuation of application No. PCT/JP2023/017622, filed on Feb. 10, 2023.

(30) Foreign Application Priority Data
Jul. 28, 2022 (JP) 2022-120674

(51) Int. Cl. G02B 5/30; G02B 1/04; G02F 1/1335

(52) U.S. Cl. CPC G02B 5/3033; G02B 1/04; G02F 1/133528

(57) ABSTRACT

A translucent resin composition comprises a transparent resin, and a natural fiber having a birefringence Δn of 0.013 to 0.15 and an average particle size of 2 to 100 μm. The translucent resin composition contains 1 to 20 parts by mass of natural fiber with respect to 100 parts by mass of transparent resin. The translucent resin composition is used for depolarization. The natural fiber is an animal fiber.

### CROSS-REFERENCE TO RELATED APPLICATION(S)

This application is a continuation of International Patent Application No. PCT/JP2023/017622 filed on May 10, 2023, which claims priority to and the benefit of Japanese Patent Application No. 2022-120674 filed on Jul. 28, 2022, the entire disclosures of which are incorporated herein by reference.

### TECHNICAL FIELD

The present invention relates to a translucent resin composition, an adhesive agent, an optical film, and a display device.

### BACKGROUND ART

A liquid crystal display device includes a liquid crystal layer, and two polarizing plates that are arranged to sandwich the liquid crystal layer and have transmission polarization directions orthogonal to each other. Hence, light emitted from the display screen of the liquid crystal display device is linearly polarized light. Note that the device is not limited to the liquid crystal display device if it emits light in a polarization state. For example, if a user wearing polarized sunglasses observes the display screen, the brightness of the display screen viewed by the user is lower than in a case where the display screen is observed without polarized sunglasses. This is because the emission light from the display screen is not transmitted through the polarized sunglasses in accordance with the angle made by the polarization direction of the emission light from the display screen and the transmission polarization direction of the polarized sunglasses. For example, if the polarization direction of the emission light and the transmission polarization direction of the polarized sunglasses are orthogonal to each other, the user wearing the polarized sunglasses cannot view the display screen at all. This phenomenon is called a blackout. To solve the problem of low visibility in observing the display screen by the user wearing the polarized sunglasses, the following techniques have been proposed.

PTL 1 discloses a technique in which in a liquid crystal display device, a retardation plate (¼ wavelength plate) is provided on a side closer to a user than a polarizing plate on the viewing side of the user, thereby converting linearly polarized light from a display screen into circularly polarized light.

PTL 2 discloses a technique in which in a liquid crystal display device, a polymer film having a very high birefringence (that is, having a very large retardation) is provided on a side closer to a user than the polarizing plate on the viewing side of the user, thereby shortening the period of a transmittance variation according to a wavelength between a polarizing plate and the polymer film.

PTL 3 discloses a technique in which a medium transparent to visible light and a plurality of crystal materials having a birefringence and dispersed in the medium are provided, thereby randomizing the polarization state of incident visible light such that visible light whose degree of polarization is lower than that of the visible light that has entered the transparent medium is emitted.

PTL 4 discloses a technique in which a film obtained by dispersing a very short fiber in a translucent resin is used, thereby canceling linearly polarized light.

PTL 5 discloses a technique in which a very short fiber is contained in a transparent matrix material, thereby canceling linearly polarized light.

### CITATION LIST

### Patent Literature

PTL 1: Japanese Patent Laid-Open No. 2005-352068
PTL 2: Japanese Patent Laid-Open No. 2011-107198
PTL 3: International Publication No. 2019/026854
PTL 4: Japanese Patent Laid-Open No. 2009-217192
PTL 5: Japanese Patent Laid-Open No. 2008-310310

### SUMMARY OF INVENTION

### Technical Problem

However, in the technique of PTL 1, since the wavelength dependency (dispersion characteristic) of the phase difference in the retardation plate is not taken into consideration, the user recognizes color unevenness on the display screen. In the technique of PTL 2, if a light source formed by combining red, green, and blue light-emitting diodes (RGB-LEDs) in which the spectrum widths of light emission spectra are relatively narrow is used as the light source of the liquid crystal display device, the user recognizes color unevenness on the display screen. In the technique of PTL 3, the clarity and the contrast ratio of the display screen are not sufficient. In the technique of PTL 4, since the haze of the film is large, the chromaticity change amount, the clarity, and the contrast are not excellent. In the technique of PTL 5, the chromaticity change amount, the clarity, and the contrast when the user views the display screen are not sufficient. As described above, in the techniques of PTLs 1 to 5, when the user observes the display screen, the color of an image on the display screen is displayed in a color different from the original color.

Hence, the present invention has as its object to provide a translucent resin composition that suppresses a change of the color of an image on a display screen when a user observes the display screen, an adhesive agent, an optical film, and a display device.

### Solution to Problem

The present invention in its one aspect provides a translucent resin composition comprising a transparent resin, and a natural fiber having a birefringence Δn of 0.013 to 0.15 and an average particle size of 2 to 100 μm, wherein the translucent resin composition contains 1 to 20 parts by mass of natural fiber with respect to 100 parts by mass of transparent resin, wherein the translucent resin composition is used for depolarization, wherein the natural fiber is an animal fiber, wherein the average particle size is a particle diameter (D50: median diameter) corresponding to 50% in the volume-based cumulative particle size distribution measured by the laser diffraction method, and wherein the birefringence Δn is determined based on a maximum retardation R, which corresponds to an interference color on a microregion of particle of the natural fiber observed in a crossed Nicol state using a polarizing microscope, and Δn=R/t (where t is the average particle size of the natural fiber).

### Advantageous Effects of Invention

According to the present invention, it is possible to provide a translucent resin composition that suppresses a change of the color of an image on a display screen when a user observes the display screen, an adhesive agent, an optical film, and a display device.

Other features and advantages of the present invention will be apparent from the following description taken in conjunction with the accompanying drawings. Note that the same reference numerals denote the same or like components throughout the accompanying drawings.

### BRIEF DESCRIPTION OF DRAWINGS

The accompanying drawings, which are incorporated in and constitute a part of the specification, illustrate embodiments of the invention and, together with the description, serve to explain principles of the invention.

FIG. 1A is a view showing a polarizing microscope photograph of an acrylic adhesive agent containing silk powder;

FIG. 1B is an enlarged view of a part of the whole image shown in FIG. 1A;

FIG. 1C is a view showing a SEM image indicating an example of silk powder;

FIG. 2A is a view showing a SEM image of silk powder SP;

FIG. 2B is a view showing a SEM image of silk powder S15;

FIG. 2C is a view showing a SEM image of silk powder navis naturace;

FIG. 3 is an exploded perspective view showing an example of a display device according to the embodiment;

FIG. 4A is a view showing an image obtained by capturing, in a crossed Nicol state, an image of a display screen with an optical film of Example 3 pasted thereon;

FIG. 4B is a view showing an image obtained by capturing, in a crossed Nicol state, an image of a display screen with an optical film of Comparative Example 1 pasted thereon;

FIG. 5 is a schematic view for explaining a method of evaluating a rainbow pattern;

FIG. 6 is a schematic view for explaining a method of evaluating the wavelength dependence of a transmittance;

FIG. 7A is a view showing the chromaticity measurement result of a reference example under measurement condition 1;

FIG. 7B is a view showing the chromaticity measurement result of Example 3 (measurement form 1) under measurement condition 1;

FIG. 7C is a view showing the chromaticity measurement result of Example 3 (measurement form 2) under measurement condition 1;

FIG. 7D is a view showing the chromaticity measurement result of Example 5 (measurement form 1) under measurement condition 1;

FIG. 7E is a view showing the chromaticity measurement result of Example 5 (measurement form 2) under measurement condition 1;

FIG. 7F is a view showing the chromaticity measurement result of Example 6 (measurement form 1) under measurement condition 1;

FIG. 7G is a view showing the chromaticity measurement result of Example 6 (measurement form 2) under measurement condition 1;

FIG. 7H is a view showing the chromaticity measurement result of Comparative Example 7 under measurement condition 1;

FIG. 8A is a view showing the chromaticity measurement result of the reference example under measurement condition 2;

FIG. 8B is a view showing the chromaticity measurement result of Example 3 (measurement form 1) under measurement condition 2;

FIG. 8C is a view showing the chromaticity measurement result of Example 3 (measurement form 2) under measurement condition 2;

FIG. 8D is a view showing the chromaticity measurement result of Example 5 (measurement form 1) under measurement condition 2;

FIG. 8E is a view showing the chromaticity measurement result of Example 5 (measurement form 2) under measurement condition 2;

FIG. 8F is a view showing the chromaticity measurement result of Example 6 (measurement form 1) under measurement condition 2;

FIG. 8G is a view showing the chromaticity measurement result of Example 6 (measurement form 2) under measurement condition 2;

FIG. 8H is a view showing the chromaticity measurement result of Comparative Example 7 under measurement condition 2;

FIG. 9A is a view showing the wavelength dependence of transmittances in a parallel Nicol state; and

FIG. 9B is a view showing the wavelength dependence of transmittances in a crossed Nicol state.

### DESCRIPTION OF EMBODIMENTS

Hereinafter, embodiments will be described in detail with reference to the attached drawings. Note, the following embodiments are not intended to limit the scope of the claimed invention, and limitation is not made to an invention that requires a combination of all features described in the embodiments. Two or more of the multiple features described in the embodiments may be combined as appropriate. Furthermore, the same reference numerals are given to the same or similar configurations, and redundant description thereof is omitted.

### <Translucent Resin Composition>

A translucent resin composition according to this embodiment contains a transparent resin, and a natural fiber having an average particle size of 2 to 100 μm, and is used for depolarization.

The translucent resin composition according to an embodiment of the present invention contains a transparent resin, and a natural fiber having a maximum retardation of 300 to 1,300 nm and an average particle size of 2 to 100 μm, contains 1 to 20 parts by mass of natural fiber with respect to 100 parts by mass of transparent resin, and is used for depolarization.

A mechanism that produces an effect of suppressing a change of the color of an image on a display screen with an optical film (to be described later) pasted thereon by causing the translucent resin composition to contain a natural fiber having the average particle size and/or the maximum retardation defined above will be described here.

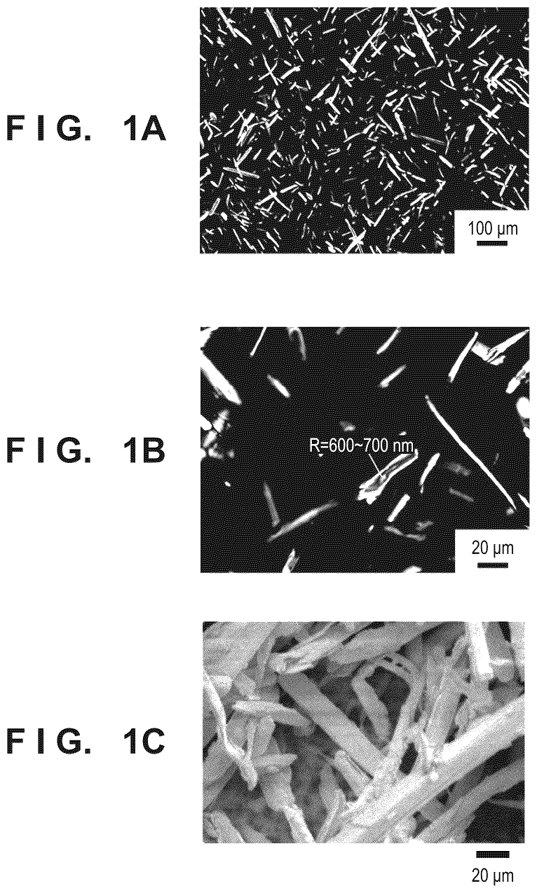

FIG. 1A is a view showing a polarizing microscope photograph of an acrylic adhesive agent containing silk powder. The silk powder means silk powder used by the present inventor to make preliminary examinations according to the present invention, and is silk powder having substantially the same average particle size (about 20 μm) as silk powder SP to be described later. Note that the acrylic adhesive agent means an acrylic adhesive agent of Example 9 to be described later.

FIG. 1B is an enlarged view of a part of the whole image shown in FIG. 1A. FIG. 1C is a view showing a SEM image indicating an example of silk powder.

Based on an interference color in FIG. 1B, the maximum value of a retardation R of the silk powder is 600 to 700 nm, and the average particle size (thickness) t of the silk powder is about 8 μm. Here, a method of determining the maximum value of the retardation R of silk powder will be described. A film was set in a polarizing microscope (BX51 available from OLYMPUS CORPORATION), and the interference color of silk powder was observed in a crossed Nicol state. An interference color chart showing the relationship between the retardation R and an interference color and the interference color of the particles of the silk powder in FIG. 1B were compared, thereby determining the maximum retardation R corresponding to the observed interference color. If the maximum retardation R is 600 to 700 nm, all interference colors are distributed in microregions of particles. The present inventor found that the distribution of all interference colors in microregions of particles contribute to suppression of a change of the color of an image. Here, a birefringence Δn of the silk powder is calculated using the retardation R, the average particle size t, and following equation (1). Hence, the birefringence Δn is 0.075 to 0.0875.

$$Δ n = R / t \qquad ( 1 )$$

The birefringence Δn (=0.075 to 0.0875) of silk powder is smaller than the birefringence Δn (=0.172) of calcite. As described above, in this embodiment, the birefringence Δn of the silk powder was determined based on the maximum retardation R of the silk powder. In addition, the present inventor specifically examined, based on the birefringence Δn of the silk powder calculated above and test results to be described later, the numerical value range of the birefringence Δn of the silk powder with which the effect of suppressing a change of the color of an image is obtained. Hence, from the viewpoint of suppressing a change of the color of an image, the birefringence Δn of the silk powder according to the embodiment is 0.013 to 0.15, 0.014 to 0.15, 0.016 to 0.15, 0.018 to 0.15, 0.020 to 0.15, or 0.022 to 0.15. here, the present inventor found that an acrylic adhesive agent containing silk powder with a low birefringence Δn has the effect of suppressing a change of the color of an image on the display screen in the crossed Nicol state. Hence, the present inventor made examinations to suppress a change of a color of the image on the display screen by changing the average particle size of the natural fiber contained in the translucent resin composition to various sizes and using the low birefringence Δn of the natural fiber.

From the viewpoint of increasing the transmission property by evenly dispersing the natural fiber in the transparent resin, the translucent resin composition according to the embodiment contains 20 parts by mass or less, preferably 15 parts by mass or less, or more preferably 10 parts by mass or less of natural fiber with respect to 100 parts by mass of transparent resin. On the other hand, from the viewpoint of improving the depolarization performance, the translucent resin composition according to the embodiment contains 1 parts by mass or more, preferably 1.4 parts by mass or more of natural fiber with respect to 100 parts by mass of transparent resin. For example, the translucent resin composition according to the embodiment contains 1 to 20 parts by mass, preferably 1.4 to 15 parts by mass, and more preferably 1.4 to 10 parts by mass of natural fiber with respect to 100 parts by mass of transparent resin.

### (Natural Fiber)

The natural fiber is a fiber whose main raw material is a natural material. The natural fiber according to the embodiment includes at least one of a plant fiber and an animal fiber.

From the viewpoint of increasing the clarity of an image, the average particle size of the natural fiber according to the embodiment is 2 to 100 μm, preferably 2 to 30 μm, and more preferably 3 to 25 μm. Here, if the average particle size of the natural fiber is smaller than 2 μm, the clarity of an image lowers. Also, if the average particle size of the natural fiber exceeds 100 μm, the clarity of an image lowers.

From the viewpoint of suppressing a change of a color of the image, the maximum retardation of the natural fiber according to the embodiment is 300 to 1,300 nm, 300 to 1,200 nm, 300 to 1,100 nm, or 300 to 1,000 nm. Here, if the maximum retardation of the natural fiber is less than 300 nm, all interference colors are not distributed in the microregions of the particles of the natural fiber and, therefore, the color of an image changes. Also, if the maximum retardation of the natural fiber exceeds 1,300 nm, all interference colors are distributed in the microregions of the particles of the natural fiber, but the color of an image changes.

From the viewpoint of suppressing a change of the color of an image, the birefringence Δn of the natural fiber according to the embodiment is 0.013 to 0.15, 0.014 to 0.15, 0.016 to 0.15, 0.018 to 0.15, 0.020 to 0.15, or 0.022 to 0.15. Here, if the birefringence Δn of the natural fiber is less than 0.013, the color of an image changes. On the other hand, if the birefringence Δn of the natural fiber exceeds 0.15, the color of an image changes.

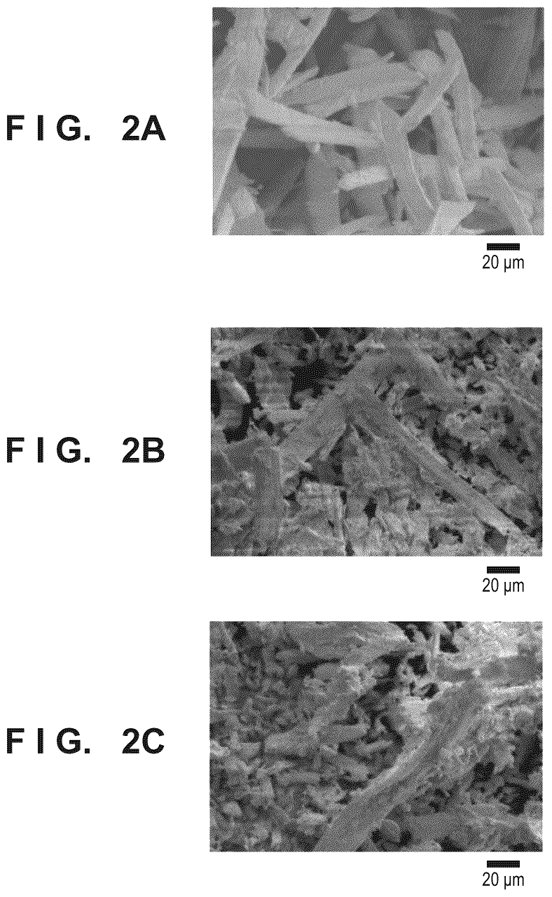

FIG. 2A is a view showing a SEM image of silk powder SP. The silk powder SP is a natural fiber contained in the translucent resin composition according to the present invention. The average particle size of the silk powder SP is about 20 μm. Note that the average particle size in this specification means a particle diameter (D50: median diameter) corresponding to 50% in the volume-based cumulative particle size distribution measured by the laser diffraction method. The average particle size can be measured using a particle size distribution measuring apparatus using the laser diffraction method.

FIG. 2B is a view showing a SEM image of silk powder S15. The silk powder S15 is a natural fiber contained in the translucent resin composition according to the present invention. The average particle size of the silk powder S15 is about 7 to 9 μm.

FIG. 2C is a view showing a SEM image of silk powder navis naturace. The silk powder navis naturace is a natural fiber contained in the translucent resin composition according to the present invention. The average particle size of the silk powder navis naturace is about 3 to 5 μm.

A plant fiber is a fiber derived from a plant and includes, for example, cellulose fiber, Manila hemp, hemp, bamboo, coconut fiber, cotton, jute, kapok, linen, ramie, and sisal hemp. Note that one type of the above-described plant fibers may be used alone, or two or more types may be used in combination.

An animal fiber is a fiber derived from an animal and includes, for example, alpaca, Angora, camel (camel hair), cashmere, mohair (Angora goat hair), pashmina, Qiviut (musk-ox hair), silk, vicuña, and wool. Note that one type of the above-described animal fibers may be used alone, or two or more types may be used in combination.

In the embodiment, as the natural fiber, a natural fiber (for example, silk or the like) of a protein such as fibroin or a natural fiber (for example, cellulose or the like) of polysaccharide can be used.

### (Transparent Resin)

The transparent resin is a material that is the base material of the translucent resin composition. The transparent resin includes an inorganic polymer, an organic polymer, and a hybrid polymer of organic and inorganic polymers.

“Transparent” of the transparent resin indicates that if a film has a thickness of 50 μm, the transmittance to light in a visible light range (360 to 830 nm) is preferably 80% or more, and more preferably 90% or more.

From the viewpoint of suppressing light scattering by the natural fiber, the refractive index of the transparent resin according to the embodiment is 1.4 to 1.7, and preferably 1.45 to 1.68.

Inorganic polymers are polymers containing inorganic elements and inorganic components, and include natural polymers and synthetic polymers. The natural polymers include glass, silicates, and minerals. The synthetic polymers include polydimethylsiloxane, polycarbosilane, and polyphosphazene.

Organic polymers include natural polymers and synthetic polymers in which main constituent components of an organic compound, such as carbon, hydrogen, oxygen, and nitrogen, form a repetitive structure. The natural polymers include, for example, regenerated cellulosic polymers such as cellophane and triacetyl cellulose. The synthetic polymers include, for example, vinyl resins, polycondensation resins, polyaddition resins, addition-condensation resins, and ring-opening polymerization resins.

### (Vinyl Resins)

Vinyl resins include general-purpose resins such as polyolefin resins, vinyl chloride resins, vinyl acetate resins, fluororesins, and (meth)acrylic resins, engineering plastics obtained by vinyl polymerization, super engineering plastics, and the like.

Polyolefin resins include homopolymers or copolymers of ethylene, propylene, styrene, butadiene, butene, isoprene, chloroprene, isobutylene, isoprene, and the like, and cyclic olefin resins with norbornene skeleton.

Vinyl chloride resins include homopolymers or copolymers of vinyl chloride, vinylidene chloride, and the like.

Vinyl acetate resins include polyvinyl acetate that is a homopolymer of vinyl acetate, polyvinyl alcohol that is a hydrolyzed form of polyvinyl acetate, polyvinyl acetal obtained by making formaldehyde or n-butyraldehyde react with vinyl acetate, and polyvinyl butyral obtained by making polyvinyl alcohol, butyraldehyde react, or the like.

Fluororesins include homopolymers or copolymers of tetrachloroethylene, hexafluoropropylene, chlorotrifluoroethylene, vinylidene fluoride, vinyl fluoride, perfluoroalkyl vinyl ether, and the like.

(Meth)acrylic resins include homopolymers or copolymers of (meth)acrylic acid, (meth)acrylonitrile, (meth)acrylic ester, (meth)acrylamide, and the like. Note that in this specification, “(meth)acrylic” means “acrylic and/or methacrylic”

(Meth)acrylic acids include acrylic and methacrylic acids.

(Meth)acrylonitrile includes acrylonitrile and methacrylonitrile.

(Meth)acrylic esters include (meth)acrylic acid alkyl esters, (meth)acrylic acid monomers with cycloalkyl groups, (meth)acrylic acid alkoxyalkyl esters, and the like.

(Meth)acrylic acid alkyl esters include methyl (meth)acrylate, ethyl (meth)acrylate, butyl (meth)acrylate, phenoxyethyl (meth)acrylate, 2-ethylhexyl (meth)acrylate, cyclohexyl (meth)acrylate, benzyl (meth)acrylate, lauryl (meth)acrylate, stearyl (meth)acrylate, hydroxyethyl (meth)acrylate, and the like.

(Meth)acrylic acid monomers with cycloalkyl groups include cyclohexyl (meth)acrylate, isobornyl (meth)acrylate, and the like.

(Meth)acrylic acid alkoxyalkyl esters include 2-methoxyethyl (meth)acrylate, 2-ethoxyethyl (meth)acrylate, 2-butoxyethyl (meth)acrylate, and the like.

(Meth)acrylamides include, for example, (meth)acrylamide, and N-substituted (meth)acrylamides such as N-methyl (meth)acrylamide, N-ethyl (meth)acrylamide, N,N-dimethyl (meth)acrylamide, N,N-diethyl(meth)acrylamide, N-isopropyl (meth)acrylamide, and N-t-octyl(meth)acrylamide.

### (Polycondensation Resins)

Polycondensation resins include amide resins and polycarbonate.

Amide resins include, for example, aliphatic amide resins such as 6,6-nylon, 6-nylon, 11-nylon, 12-nylon, 4,6-nylon, 6,10-nylon, and 6,12-nylon, and aromatic polyamides made of aromatic diamines such as phenylenediamine, aromatic dicarboxylic acids such as terephthaloyl chloride and isophthaloyl chloride, and a derivative thereof, and the like.

Polycarbonate means a reactant of bisphenol A or a bisphenol that is a derivative thereof and phosgene or phenyl decarbonate.

### (Polyaddition Resins)

Polyaddition resins include ester resins, U polymers, liquid crystalline polymers, polyether ketones, polyether ether ketones, unsaturated polyesters, alkyd resins, polyimide resins, polyisulfone, polyphenylene sulfide, polyethersulfone, urethane resins, and the like.

Ester resins include aromatic polyesters, aliphatic polyesters, unsaturated polyesters, and the like.

Aromatic polyesters include copolymers of diols such as ethylene glycol, propylene glycol, and 1,4-butanediol and aromatic dicarboxylic acids such as terephthalic acid.

Aliphatic polyesters include copolymers of diols and aliphatic dicarboxylic acids such as succinic acid and valeric acid, homopolymers or copolymers of hydroxycarboxylic acids such as glycolic acid and lactic acid, copolymers of diols, aliphatic dicarboxylic acids, and hydroxycarboxylic acids, and the like.

Unsaturated polyesters include copolymers of diols, unsaturated dicarboxylic acids such as maleic anhydride, and vinyl monomers such as styrene as needed.

U polymers include copolymers made of bisphenol A or a bisphenol that is a derivative thereof, terephthalic acid, isophthalic acid, and the like.

Liquid crystalline polymers include copolymers of p-hydroxybenzoic acid, terephthalic acid, p,p′-dioxydiphenol, p-hydroxy-6-naphthoic acid, ethylene polyterephthalate, and the like.

Polyether ketones include homopolymers or copolymers of 4,4′-difluorobenzophenone, 4,4′-dihydrobenzophenone, and the like.

Polyether ether ketones include copolymers of 4,4′-difluorobenzophenone, hydroquinone, and the like.

Alkyd resins include copolymers made of higher fatty acids such as stearic acid and palmitic acid, dibasic acids such as phthalic anhydride, and polyols such as glycerin.

Polyimide resins include pyromellitic acid type polyimides that are copolymers of anhydrous polymellitic acid, 4,4′-diaminodiphenyl ether, and the like, trimellitic acid type polyimides that are copolymers of anhydrous trimellitic acid chloride, aromatic diamine such as p-phenylenediamine, a diisocyanate compound, and the like, biphenyl type polyimides made of biphenyl tetracarboxylic acid, 4,4′-diaminodiphenyl ether, p-phenylenediamine, and the like, benzophenone type polyimides made of benzophenone tetracarboxylic acid, 4,4′-diaminodiphenyl ether, and the like, and bismaleimide type polyimides made of bismaleimide, 4,4′-diaminodiphenylmethane, and the like.

Polyisulfone includes copolymers of 4,4′-dichlorodiphenylsulfone, bisphenol A, and the like.

Polyphenylene sulfide includes copolymers of p-dichlorobenzene, sodium sulfide, and the like.

Polyethersulfone includes polymers of 4-chloro-4′-hydroxydiphenylsulfone.

Urethane resins are copolymers of diisocyanates and diols.

Diisocyanates include dicyclohexylmethane diisocyanate, 1,6-hexamethylene diisocyanate, isophorone diisocyanate, 1,3-cyclohexylene diisocyanate, 1,4-cyclohexylene diisocyanate, 2,4-triylene diisocyanate, 2,6-triylene diisocyanate, 4,4′-diphenylmethane diisocyanate, 2,4′-diphenylmethane diisocyanate, 2,2′-diphenylmethane diisocyanate, and the like.

Diols include diols of relatively low molecular weights such as ethylene glycol, propylene glycol, 1,3-propanediol, 1,3-butanediol, 1,4-butanediol, 1,5-pentanediol, 3-methyl-1,5-pentanediol, 1,6-hexanediol, neopentyl glycol, diethylene glycol, trimethylene glycol, triethylene glycol, tetraethylene glycol, dipropylene glycol, tripropylene glycol, and cyclohexane dimethanol, polyester diol, polyether diol, polycarbonate diol, and the like.

### (Addition-Condensation Resins)

Addition-condensation resins include phenol resins, urea resins, melamine resins, and the like.

Phenol resins include homopolymers or copolymers of phenol, cresol, resorcinol, phenylphenol, bisphenol A, bisphenol F, and the like.

Urea resins are copolymers of formaldehyde and urea.

Melamine resins are copolymers of formaldehyde and melamine.

### (Ring-Opening Polymerization Resins)

Ring-opening polymerization resins include polyalkylene oxide, polyacetal, epoxy resins, and the like.

Polyalkylene oxide includes homopolymers or copolymers of ethylene oxide, propylene oxide, and the like.

Polyacetal includes copolymers of trioxane, formaldehyde, ethylene oxide, and the like.

Epoxy resins include aliphatic epoxy resins made of polyhydric alcohols such as ethylene glycol and epichlorohydrin, aliphatic epoxy resins made of bisphenol A and epichlorohydrin, and the like.

The transparent resin according to the embodiment includes one of (meth)acrylic resins, polycarbonate resins, cyclic olefin resins, polystyrenes, and acetate resins. Also, from the viewpoint of increasing the clarity of an image, the transparent resin according to the embodiment includes at least one of polyester resins, polysulfone resins, polycarbonate resins, and cyclic olefin resins.

### (Dispersion Medium)

A dispersion medium is an organic solvent used when producing a polymer solution containing the translucent resin composition, and contains, for example, methylene chloride and ethyl acetate. The translucent resin composition according to the embodiment contains 300 to 800 parts by mass, preferably 400 to 700 parts by mass, or more preferably 500 to 600 parts by mass of dispersion medium with respect to 100 parts by mass of transparent resin.

### <Adhesive Agent>

The adhesive agent according to the present invention contains the translucent resin composition and adheres adherends of different materials or adherends of the same material. Also, the translucent resin composition is used as, for example, an adhesive. The adhesive agent or adhesive can adhere an optical film to be described later and a base material. Adherends of different materials are, for example, an adherend of an organic material and an adherend of an inorganic material. Also, adherends of the same material are, for example, an adherend of an organic material and an adherend of an organic material.

### <Optical Film>

An optical film includes a layer made of the translucent resin composition, and a film formed by thermally melting the translucent resin composition. The optical film according to the present invention includes not only a form of a single optical film but also a form of an optical film provided on at least one surface of a base material. Note that as for the mode of the layer made of the translucent resin composition, it is a liquid before curing/drying and is a solid after curing/drying. That is, after curing/drying of the translucent resin composition, the optical film does not have adhesion. At this time, the optical film can be adhered to the base material by the above-described adhesive agent and/or adhesive.

The thickness of the optical film (except the base material) according to the embodiment is 1 to 120 μm, preferably 5 to 110 μm, and more preferably 10 to 100 μm.

The base material is, for example, a silane-treated glass substrate, a plastic substrate, or a plastic film (PET film, or the like).

A method of applying the translucent resin composition to the base material includes, for example, a bar coat method, a knife coat method, a roll coat method, a blade coat method, a die coat method, a gravure coat method, and the like. After a coat is formed by applying the translucent resin composition to the base material using one of the above-described methods, curing/drying is performed at 60° C. to 200° C., preferably 70° C. to 170° C., and more preferably 80° C. to 140° C.

A degree of polarization (%) obtained by the optical film according to the embodiment is preferably 90% or less, and more preferably 87% or less from the viewpoint of obtaining a depolarization effect.

The haze (%) of the optical film according to the embodiment is preferably 50 or less, and more preferably 40 or less from the viewpoint of suppressing a change of the color of an image on the display screen.

The chromaticity change amount by the optical film according to the embodiment is preferably 0.04 or less, and more preferably 0.02 or less from the viewpoint of suppressing a change of the color of an image on the display screen.

The the contrast ratio by the optical film according to the embodiment is preferably 70% or more, and more preferably 75% or more from the viewpoint of suppressing a change of the color of an image on the display screen.

### <Display Device>

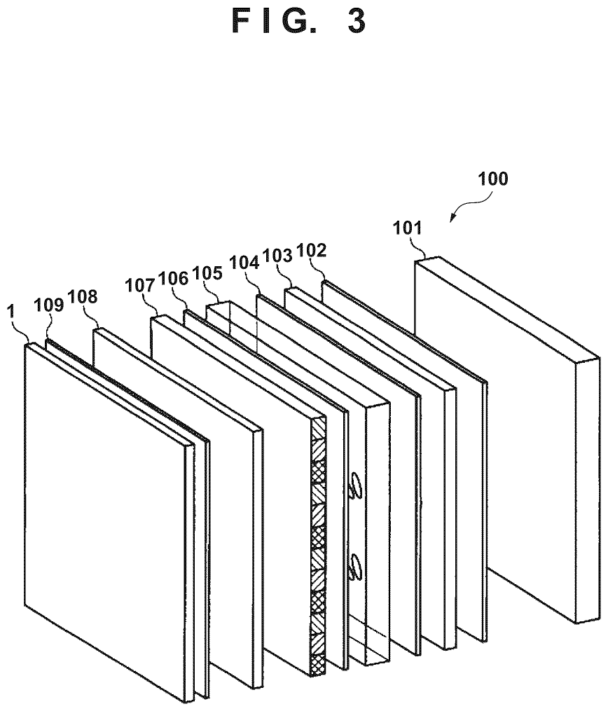

FIG. 3 is an exploded perspective view showing an example of a display device according to the embodiment. Note that since an optical film 1 and an adhesive agent (not shown) to be described below contain the translucent resin composition according to the present invention, a detailed description of the translucent resin composition will be omitted.

A display device according to the embodiment, which emits light in a polarization state, includes at least one of an optical film and an adhesive agent arranged on the observer side of the display device. The at least one of the optical film and the adhesive agent according to the embodiment contains the translucent resin composition.

A display device 100 is a device that emits light in a polarization state, and includes, for example, a liquid crystal display device (to be also referred to as an LCD hereinafter) and an organic EL display. The display device 100 has a configuration in which a backlight 101, a polarizing plate 102, a retardation film 103, a glass substrate 104 with transparent electrode, a liquid crystal layer 105, a glass substrate 106 with transparent electrode, an RGB color filter 107, a retardation film 108, a polarizing plate 109, and the optical film 1 according to this embodiment are stacked in this order. Also, from the viewpoint of protecting the screen of the display device 100, a protective film (for example, a PET film) (not shown) may be provided between the polarizing plate 109 and the optical film 1. Note that the optical film 1 can be adhered to the polarizing plate 109 or the protective film (not shown) by the adhesive agent according to the present invention or a known adhesive agent. Here, the display device 100 can have a configuration in which the optical film 1 and the adhesive agent according to the present invention are incorporated in a liquid crystal display device having a known configuration. Also, the display device 100 may not include the optical film 1 as an essential component and may include only the adhesive agent according to the present invention, which has the same depolarization effect as the optical film 1. Furthermore, the optical film 1 may not be provided on the polarizing plate 109, as shown in FIG. 3. For example, one or more optical films 1 may be arranged at an arbitrary position from the backlight 101 to the polarizing plate 109.

In the display device 100, the optical film 1 is incorporated on the observer side of the polarizing plate 109, that is, on the opposite side of the backlight 101. Hence, light emitted from the polarizing plate 109 enters the optical film 1 and then exits while the polarization state of the light is randomized. As a result, if the user (observer) observes the display screen through polarized sunglasses, no blackout occurs on the display screen of the display device 100, and a change of the color of an image can be suppressed. Furthermore, even in a case where the user observes the display screen from an oblique direction without wearing polarized sunglasses, the color of an image on the display screen may change. This is because the light from the oblique direction is partially polarized and, therefore, the same effect as insertion of a weak polarizing plate, that is, the same effect as wearing of polarized sunglasses is generated weak.

In the recent display device 100, the type of the liquid crystal is changed, and a viewing angle compensation film is used, thereby designing the display device 100 such that the brightness and color of an image when user obliquely observes the display device 100 do not change. In general, to prevent flaws, light reflection, blue light, and the like on the screen of the display device 100 (for example, a smartphone, a tablet terminal, various kinds of monitors, and the like), many users use the display device 100 on which a protective film having various kinds of functions are pasted. However, since a protective film (for example, a polyester film) has birefringence, a change of the color of an image (more specifically, a rainbow pattern on the screen) occurs when the user obliquely observes the screen of the display device 100. Hence, the present invention (at least one of the optical film and the adhesive agent) has an effect of suppressing a change of the color of an image even in a case where the user views a TV or a signage without wearing polarized sunglasses, or a protective film is pasted on the screen of the display device 100. In addition, the present invention can suppress cost as compared to an existing means (for example, a zero birefringence film or a super birefringence film) for suppressing a change of the color of an image due to a protective film.

### <Manufacturing of Translucent Resin Composition>

Table 1 shows transparent resins used to manufacture translucent resin compositions of Examples 1 to 9 and the refractive indices of the transparent resins. An acrylic adhesive agent of Example 9 indicates that it contains a polymer obtained by copolymerizing 20 parts by mass of BA and 80 parts by mass of PHEA with respect to 100 parts by mass of transparent resin.

TABLE 1

| | | | | | | | | | Example |
|---|---|---|---|---|---|---|---|---|---|
| | | | | | | | | | 9 |
| | | | | | | | | | acrylic |
| | | | | | | | | | adhesive |
| | Ex- | Ex- | Ex- | Ex- | Ex- | Ex- | Ex- | Ex- | agent |
| | ample | ample | ample | ample | ample | ample | ample | ample | (BA/ |
| Transparent | 1 | 2 | 3 | 4 | 5 | 6 | 7 | 8 | PHEA = |
| resin | PMMA | PC | PC | PC | PC | PC | PC | PC | 20/80) |
| Refractive | 1.489 | 1.586 | 1.586 | 1.586 | 1.586 | 1.586 | 1.586 | 1.586 | 1.54 |
| index | | | | | | | | | |

*Explanation of Abbreviations
PMMA: acrylic resin
PC: polycarbonate
BA: butyl acrylate
PHEA: phenoxyethyl acrylate

Table 2 shows natural fibers used to manufacture the translucent resin compositions of Examples 1 to 9 and the average particle sizes (the unit is μm) of the natural fibers.

TABLE 2

| | | | | | Ex- | | Ex- | Ex- | |
|---|---|---|---|---|---|---|---|---|---|
| | Ex- | Ex- | Ex- | Ex- | ample | Ex- | ample | ample | Ex- |
| | ample | ample | ample | ample | 5 | ample | 7 | 8 | ample |
| | 1 | 2 | 3 | 4 | silk | 6 | hemp | hemp | 9 |
| | silk | silk | silk | silk | powder | silk | cellulose | cellulose | silk |
| Natural | powder | powder | powder | powder | navis | powder | powder | powder | powder |
| fiber | SP | SP | SP | SP | naturace | S15 | R30 | RP | SP |
| Average | 20 | 20 | 20 | 20 | 4 | 8 | 10 | 20 | 20 |
| particle | | | | | | | | | |
| size | | | | | | | | | |
| (μm) | | | | | | | | | |

Table 3 shows raw material blends of the transparent resins, the natural fibers, and solvents used to manufacture the translucent resin compositions of Examples 1 to 9.

TABLE 3

| | | Ex- | Ex- | Ex- | Ex- | Ex- | Ex- | Ex- | Ex- | Ex- |
|---|---|---|---|---|---|---|---|---|---|---|
| Translucent resin | | ample | ample | ample | ample | ample | ample | ample | ample | ample |
| composition | | 1 | 2 | 3 | 4 | 5 | 6 | 7 | 8 | 9 |
| Trans- | PMMA | 100 | | | | | | | | |
| parent | PC | | 100 | 100 | 100 | 100 | 100 | 100 | 100 | |
| resin | acrylic | | | | | | | | | 100 |
| | adhesive | | | | | | | | | |
| | agent | | | | | | | | | |
| | (BA/ | | | | | | | | | |
| | PHEA = | | | | | | | | | |
| | 20/80) | | | | | | | | | |
| Natural | silk powder | 2 | 2 | 10 | 10 | | | | | 1.4 |
| fiber | SP | | | | | | | | | |
| | silk powder | | | | | 10 | | | | |
| | navis | | | | | | | | | |
| | naturace | | | | | | | | | |
| | silk powder | | | | | | 10 | | | |
| | S15 | | | | | | | | | |
| | hemp | | | | | | | 10 | | |
| | cellulose | | | | | | | | | |
| | powder R30 | | | | | | | | | |
| | hemp | | | | | | | | 10 | |
| | cellulose | | | | | | | | | |
| | powder RP | | | | | | | | | |
| Solvent | methylene | appro- | appro- | appro- | appro- | appro- | appro- | appro- | appro- | appro- |
| | chloride | priate | priate | priate | priate | priate | priate | priate | priate | priate |
| | | amount | amount | amount | amount | amount | amount | amount | amount | amount |

* Each numerical value in the table indicates the parts by mass of an active component.
Explanation of Abbreviations
PMMA: acrylic resin
PC: polycarbonate
BA: butyl acrylate
PHEA: phenoxyethyl acrylate

### Example 1

Based on the raw material blend of Example 1 shown in Table 3, 2 g (active component: 2 parts by mass) of silk powder SP (Izumi Senko) as a natural fiber and an appropriate amount of methylene chloride (Wako Chemicals Industry) (parts by mass 5 to 6 times larger than PMMA) as a solvent were added to a vial. After the natural fiber in the solvent was sufficiently dispersed using an ultrasonic cleaning machine, 100 g (active component: 100 parts by mass) of pellet of PMMA (Wako Chemicals Industry) as a transparent resin was added to the vial. The mixture in the vial was stirred by a shaker until the transparent resin was completely dissolved, thereby producing a polymer solution.

The polymer solution was spread into a sheet on a release PET film and cast by an applicator. The cast film spread on the PET film was dried at room temperature (20° C. to 25° C.) for 1 hr. The dried cast film was released from the PET film, and the cast film was sandwiched between paper and glass and dried in a decompression environment at 90° C. for 10 hrs or more. An optical film having a thickness of 50 μm was thus obtained. Note that the thickness of the optical film was measured using a dial thickness gauge (PEACOCK: OZAKI MFG. Co., Ltd.)

### Examples 2 to 8

In each of Examples 2 to 8, a translucent resin composition and an optical film were obtained by performing the same steps as in Example 1 based on the raw material blending amounts shown in Table 3.

### Example 9

In Example 9, an adhesive agent of a translucent resin composition was obtained by performing the same steps as in Example 1 based on the raw material blending amounts shown in Table 3. Note that in Example 9, the adhesive agent of the translucent resin composition was applied to a glass substrate and dried, thereby producing an “optical test piece”. Note that the “optical test piece” of Example 9 was produced to confirm whether a useful optical characteristic was obtained not only in the form of an optical film but also in the form of an adhesive agent.

### Comparative Examples 1 to 10

Table 4 shows transparent resins used to manufacture translucent resin compositions of Comparative Examples 1 to 4 and 6 and the refractive indices of the transparent resins. Note that ¼ retardation plates of Comparative Examples 5, 8, and 9 and a PET film of Comparative Example 7 are not relevant to the manufacturing of the translucent resin compositions. That is, Comparative Example 5 and Comparative Examples 7 to 9 were used for performance comparison between the optical films of Examples 1 to 8 and the optical test piece of Example 9. Here, Comparative Example 7 (PET film) was used to compare rainbow pattern evaluation to be described later with Examples 3, 5, and 6. Also, the optical characteristic of the ¼ retardation plate of each of Comparative Examples 5, 8, and 9 will be described. Comparative Example 5 (QWP-1) is a ¼ retardation plate of normal dispersion and has a characteristic that retardation lowers as the wavelength becomes high in the visible light range. On the other hand, Comparative Examples 8 and 9 (QWP-2 and QWP-3) are ¼ retardation plate of reverse dispersion and have a characteristic that retardation increases as the wavelength becomes high in the visible light range. However, the ¼ retardation plates of Comparative Examples 8 and 9 can hardly correctly control to a phase difference of ¼ wavelength in all visible light ranges. Hence, Comparative Examples 5, 8, and 9 were used for comparison with Examples 3, 5, and 6 in which the problem concerning ¼ wavelength phase difference control in all visible light ranges can be solved.

TABLE 4

| | Com- | Com- | Com- | Com- | Com- | Com- | Com- | Com- | Com- | Com- |
|---|---|---|---|---|---|---|---|---|---|---|
| | parative | parative | parative | parative | parative | parative | parative | parative | parative | parative |
| | Ex- | Ex- | Ex- | Ex- | Ex- | Ex- | Ex- | Ex- | Ex- | Ex- |
| Trans- | ample | ample | ample | ample | ample | ample | ample | ample | ample | ample |
| parent | 1 | 2 | 3 | 4 | 5 | 6 | 7 | 8 | 9 | 10 |
| resin, etc. | PSU | PSU | PC | PC | QWP-1 | PC | PET | QWP-2 | QWP-3 | PSU |
| Refractive | 1.489 | 1.586 | 1.586 | 1.586 | 1.586 | 1.586 | — | — | — | 1.586 |
| index | | | | | | | | | | |

* Explanation of Abbreviations
PSU: polysulfone resin
PC: polycarbonate
PET: polyethylene terephthalate
QWP-1: 1/4 retardation plate of normal dispersion (MCR140N, MeCan Imaging Inc.)
QWP-2: 1/4 retardation plate of reverse dispersion (#14-724, Edmund Optics)
QWP-3: 1/4 retardation plate of reverse dispersion (#88-252, Edmund Optics)

Table 5 shows non-natural fibers used to manufacture the translucent resin compositions of Comparative Examples 1 to 4, 6, and 10 and the average particle sizes (the unit is μm) of the non-natural fibers. Note that since Comparative Examples 5 and 7 to 9 are not relevant to the manufacturing of the translucent resin compositions, as described above, no natural fibers were used. To confirm the optical characteristic in a case where neither a natural fiber nor a non-natural fiber was used, neither a natural fiber nor a non-natural fiber was used in the translucent resin composition of Comparative Example 6. In Comparative Example 10, eight types of translucent resin compositions were manufactured using, as a non-natural fiber, calcite whose average particle size fell within the range of 0.9 to 22.5 μm. Note that the range of the average particle size from 0.9 μm to 22.5 μm includes 0.9 μm, 2.1 μm, 2.6 μm, 3.6 μm, 7.3 μm, 14.3 μm, 19.2 μm, and 22.5 μm.

TABLE 5

| | Com- | Com- | Com- | Com- | Com- | Com- | Com- | Com- | Com- | Com- |
|---|---|---|---|---|---|---|---|---|---|---|
| | parative | parative | parative | parative | parative | parative | parative | parative | parative | parative |
| | Ex- | Ex- | Ex- | Ex- | Ex- | Ex- | Ex- | Ex- | Ex- | Ex- |
| Non- | ample | ample | ample | ample | ample | ample | ample | ample | ample | ample |
| natural | 1 | 2 | 3 | 4 | 5 | 6 | 7 | 8 | 9 | 10 |
| fiber | calcite | calcite | PET | PET | — | — | — | — | — | calcite |
| Average | 0.9 | 29 | 56 | 14 | — | — | — | — | — | 0.9-22.5 |
| particle | | | | | | | | | | |
| size | | | | | | | | | | |
| (μm) | | | | | | | | | | |

* Explanation of Abbreviations
calcite: crushed calcium carbonate crystal (calcite)
PET: polyester film that was crushed at extremely low temperature

Table 6 shows raw material blends of the transparent resins, the non-natural fibers, and solvents used to manufacture the translucent resin compositions of Comparative Examples 1 to 4, 6, and 10. In Comparative Example 10, as described above, eight types of translucent resin compositions were manufactured using calcite having an average particle size within the average particle size range of 0.9 to 22.5 μm. Note that in Comparative Examples 5 and 7 to 9, manufacturing of the translucent resin composition was not performed, and the ready-made products shown in Table 6 (PET film and QWP-1 to QWP-3 as ¼ retardation plates) were prepared.

TABLE 6

| | | Com- | Com- | Com- | Com- | Com- | Com- | Com- | Com- | Com- | Com- |
|---|---|---|---|---|---|---|---|---|---|---|---|
| Translucent | | parative | parative | parative | parative | parative | parative | parative | parative | parative | parative |
| resin | | Ex- | Ex- | Ex- | Ex- | Ex- | Ex- | Ex- | Ex- | Ex- | Ex- |
| composition | | ample | ample | ample | ample | ample | ample | ample | ample | ample | ample |
| etc. | | 1 | 2 | 3 | 4 | 5 | 6 | 7 | 8 | 9 | 10 |
| Trans- | PSU | 100 | 100 | | | | | | | | 100 |
| parent | PC | | | 100 | 100 | | 100 | | | | |
| resin | QWP-1 | | | | | — | | | | | |
| etc. | PET | | | | | | | — | | | |
| | QWP-2 | | | | | | | | — | | |
| | QWP-3 | | | | | | | | | — | |
| Non- | calcite | 7 | 11 | | | | | | | | 11 |
| natural | PET | | | 6 | 6 | | | | | | |
| fiber | | | | | | | | | | | |
| Solvent | methyl- | appro- | appro- | appro- | appro- | — | appro- | — | — | — | — |
| | ene | priate | priate | priate | priate | | priate | | | | |
| | chloride | amount | amount | amount | amount | | amount | | | | |

* Each numerical value in the table indicates the parts by mass of an active component.

### <Test Method>

Using display devices to which the optical films (Examples 1 to 8 and Comparative Examples 1 to 4, 6, and 10), the optical test piece (Example 9), the PET film (Comparative Example 7), and the ¼ retardation plates (Comparative Examples 5, 8, and 9) were attached, tests of Test Examples 1 to 9 below were conducted, and performance evaluation concerning the optical characteristic was performed.

### Test Example 1, Confirmation of Depolarization

An optical film, an optical test piece, or a ¼ retardation plate was pasted to the display screen of a display device (tablet terminal, Apple), the optical film, the optical test piece, or the ¼ retardation plate was covered with a polarizing plate such that a crossed Nicol state was obtained, and the liquid crystal display device was caused to display a white video. At this time, the liquid crystal display device was viewed, and the depolarization effect was evaluated based on the following evaluation criteria.

### (Evaluation Criteria)

Present: Brightness to enable viewing of an image on the display screen exists.
Absent: Brightness to enable viewing of an image on the display screen does not exist.

### Test Example 2, Measurement of Degree of Polarization

A liquid crystal display device to which an optical film, an optical test piece, or a ¼ retardation plate was pasted was caused to display a white video in a parallel Nicol state or a crossed Nicol state. Letting Lp be the luminance measured in the parallel Nicol state, and Lc be the luminance measured in the crossed Nicol state, the degree of polarization is calculated by equation (2) below. The degree of polarization is an index indicating how close light is to perfect polarized light. For example, if the numerical value of the degree of polarization is 100%, it indicates that the light is light in one perfect polarization state. On the other hand, if the numerical value of the degree of polarization is 0%, it indicates unpolarized light (or non-polarized light). If a polarized light component is mixed, the degree of polarization takes a value from 0% to 100% in accordance with the ratio of the polarized light component. Note that to measure the luminance, a spectroradiometer (CS-2000A, KONICA MINOLTA) was used.

$$degree of polarization = \frac{\vert {L}_{p} - {L}_{C} \vert}{{L}_{p} + {L}_{C}} \times 100 \qquad ( 2 )$$

### Test Example 3, Measurement of Haze Value

Using a haze meter (SH7000, NIPPON DENSHOKU INDUSTRIES), the haze values (cloudiness values) of the optical films, the optical test piece, and the ¼ retardation plates were measured. The haze value indicates the degree of cloudiness of a measurement target. Note that the smaller the haze value is, the more transparent the measurement target is.

### Test Example 4, Measurement of Chromaticity Change Amount

The chromaticity (u′ₚ, v′ₚ) of a liquid crystal display device to which an optical film, an optical test piece, or a ¼ retardation plate was pasted in a parallel Nicol state and the chromaticity (u′_{c}, v′_{c}) in a crossed Nicol state were measured using a spectroradiometer (CS-2000A, KONICA MINOLTA). Each measured chromaticity is a value based on CIE 1976 UCS chromaticity diagram. Note that at the time of chromaticity measurement, 24 colors of the Macbeth chart were displayed on the liquid crystal display device, and a chromaticity change amount Δu′v′ for each of the 24 colors was measured. Of the chromaticity change amounts Δu′v′ for the 24 colors, the largest chromaticity change amount Δu′v′ was employed as the measurement value. Here, the chromaticity change amount Δu′v′ is calculated based on the chromaticity measured in each of the parallel Nicol state and the crossed Nicol state and equation (3). The smaller the value of the chromaticity change amount Δu′v′ is, the more difficult the user is to sense a change of the color of an image.

$$Δ {u}^{′} {v}^{′} = \sqrt{{( {u}_{p}^{′} - {u}_{c}^{′} )}^{2} + {( {v}_{p}^{′} - {v}_{c}^{′} )}^{2}} \qquad ( 3 )$$

### Test Example 5, Confirmation of Clarity

Characters were displayed on the display screen of a liquid crystal display device to which an optical film, an optical test piece, or a ¼ retardation plate was pasted. At this time, the characters on the display screen were visually observed in a crossed Nicol state, and the clarity was evaluated based on the following evaluation criteria of four levels.

### (Evaluation Criteria)

⊚: characters are sufficiently clearly displayed
O: characters are clearly displayed
Δ: characters are somewhat clearly displayed
x: characters are displayed hazy

### Test Example 6, Measurement of Contrast Ratio

A maximum luminance Lₘₐₓ when a white image was displayed on the display screen of a liquid crystal display device to which an optical film, an optical test piece, or a ¼ retardation plate was pasted (to be referred to as a measurement form hereinafter) and a minimum luminance Lₘᵢₙ when a black image was displayed were measured using a spectroradiometer (CS-2000A, KONICA MINOLTA). The contrast ratio is calculated based on the maximum luminance Lₘₐₓ, the minimum luminance Lₘᵢₙ, and equation (4). The higher the value of the contrast ratio is, the clearer the display is, and the more clearly the color difference is expressed.

$$contrast ratio = {L}_{max} / {L}_{min} \qquad ( 4 )$$

Note that when a white image is displayed on the display screen of a liquid crystal display device in a form (to be referred to as a normal form hereinafter) in which an optical film, an optical test piece, or a ¼ retardation plate is not pasted, the contrast ratio is 1119. Here, to evaluate the change of the contrast in the measurement form, the ratio of the contrast ratio was calculated based on equation (5). As described above, the contrast ratio in the normal form is “1119”. The closer the numerical value of the ratio of the contrast ratio is to 100%, the less lowering of the contrast in the measurement form is.

$$ratio of contrast ratio = ( contrast ratio in measurement form / contrast ratio in normal form ) \times 100 ( \% ) \qquad ( 5 )$$

### Test Example 7, Rainbow Pattern Evaluation

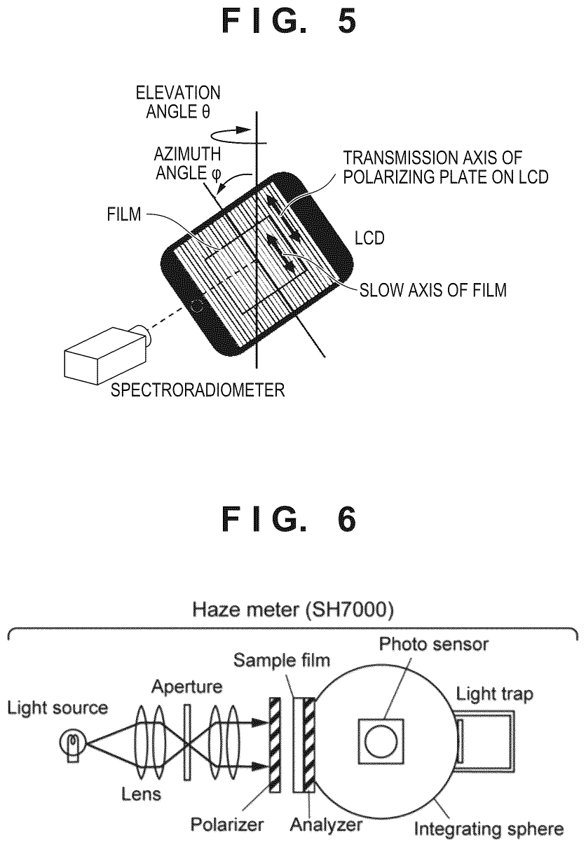

FIG. 5 is a schematic view for explaining a method of evaluating a rainbow pattern. Using a spectroradiometer (CS-2000A, KONICA MINOLTA), the chromaticity (u′, v′) of each of LDCs (MediaPad M3 lite, Huawei Device Co., Ltd.) to which the optical films of Examples 3, 5, and 6 were pasted (to be referred to as measurement form 1 hereinafter), LDCs obtained by further arranging a PET film between the optical film and the LCD in measurement form 1 (to be referred to as measurement form 2 hereinafter), and an LCD to which the PET film of Comparative Example 7 was pasted (to be referred to as measurement form 3 hereinafter) was measured. The test purpose of measurement form 2 is to confirm a rainbow pattern canceling effect in a case where the optical film of each of Examples 3, 5, and 6 is pasted to the PET film on the LCD. The PET film was pasted such that the slow axis was parallel to the transmission axis of the polarizing plate on the viewing side of the LCD (the optical film was pasted in an arbitrary direction because it has no slow axis). Here, to make the refractive index difference small on the film interface, the films were pasted while inserting an appropriate amount of water between each film (the optical film or the PET film) and the LCD and between the films (the optical film and the PET film). The angle of the LCD was defined by an elevation angle θ and an azimuth angle ϕ. The angle θ is 0° when the display surface faces the front and 90° when the display surface faces just beside. The angle ϕ is the angle of the transmission axis on the viewing side of the LCD with respect to the rotation axis of θ (see FIG. 5). In FIG. 5, the chromaticity (u′, v′) at each viewing angle when θ was rotated from 0° to 80° in a state in which ϕ=65° was fixed (to be referred to as measurement condition 1 hereinafter) and the chromaticity (u′, v′) at each viewing angle when θ was rotated from 0° to 90° in a state in which ϕ=65° was fixed (to be referred to as measurement condition 2 hereinafter) were measured. The rainbow pattern on the polarization state of each LCD was evaluated based on the following evaluation criteria.

### (Evaluation Criteria)

O: the difference between the maximum value and the minimum value of u′ and v′ is less than 0.02 in both measurement condition 1 and measurement condition 2
x: the difference between the maximum value and the minimum value of u′ or v′ is 0.02 or more in both measurement condition 1 and measurement condition 2

### Test Example 8, Evaluation of Wavelength Dependence of Transmittance

FIG. 6 is a schematic view for explaining a method of evaluating the wavelength dependence of a transmittance. A polarizing plate was attached to each of the light source side and the detector side of a haze meter (SH7000, NIPPON DENSHOKU INDUSTRIES), each of the optical films of Examples 3, 5, and 6 and QWP-1 to QWP-3 of Comparative Examples 5, 8, and 9 was set between the two polarizing plates, and a transmittance at wavelengths of 400 to 750 nm was measured. Here, a transmittance measured in a parallel Nicol state without setting the optical films and QWP-1 to QWP-3 was defined as 100%. Switching between the parallel Nicol state and a retardation film was done by rotating the polarizing plate (Analyzer in FIG. 6) on the detector side. A transmittance spectrum measured at wavelengths of 400 to 750 nm was normalized by the transmittance at 550 nm, thereby evaluating the wavelength dependence of the transmittance of each of Examples 3, 5, and 6 and Comparative Examples 5, 8, and 9 based on the following evaluation criteria.

### (Evaluation Criteria)

O: The normalized transmittance is 90% to 110% at wavelengths of 400 to 750 nm in the parallel Nicol state or the crossed Nicol state
x: The normalized transmittance has a value outside the range of 90% to 110% at wavelengths of 400 to 750 nm in the parallel Nicol state or the crossed Nicol state

### Test Example 9, Evaluation of Clarity by Pixel Pitch Difference

The purpose of Test Example 9 is to confirm the clarity of an image in a case where an optical film is pasted to each of two types of displays having different pixel pitches. In a state on which no polarizing plate existed and in a crossed Nicol state (using a polarizing plate), each of the optical films of Examples 3, 5, and 6, Comparative Example 2, and Comparative Example 10 (eight types) was pasted to each of displays with two types of pixel pitches (pixel pitch=96 μm×96 μm, and pixel pitch 294 μm×294 μm) (matching oil having a refractive index of 1.518 was used). The clarity of each of displays with the optical films pasted was visually measured. The display having a pixel pitch of 96 μm×96 μm (called a small pixel pitch) is iPad (registered trademark, 4th generation, Apple). The display having a pixel pitch of 294 μm×294 μm (called a large pixel pitch) is CD-AD198GEB-X (I-O DATA DEVICE, INC.). Here, the pixel pitch is the distance between adjacent pixels. The smaller the pixel pitch is, the higher the resolution per unit area is. The clarity was evaluated based on the following evaluation criteria.

### (Evaluation Criteria)

⊚: characters are sufficiently clearly displayed
O: characters are clearly displayed
Δ: characters are somewhat clearly displayed
x: characters are displayed hazy

### <Test Results>

Test results of Examples 1 to 9 are shown in Table 7. Test results of Comparative Examples 1 to 10 are shown in Table 8. “-” in Table 7 indicates that no test was conducted. Note that in Comparative Example 6 shown in Table 8, since depolarization was “absent”, measurement of the test items (the degree of polarization, the chromaticity change amount, and the contrast) was not performed (indicated by “-” in Table 8). “-” in Table 8 indicates that no test was conducted.

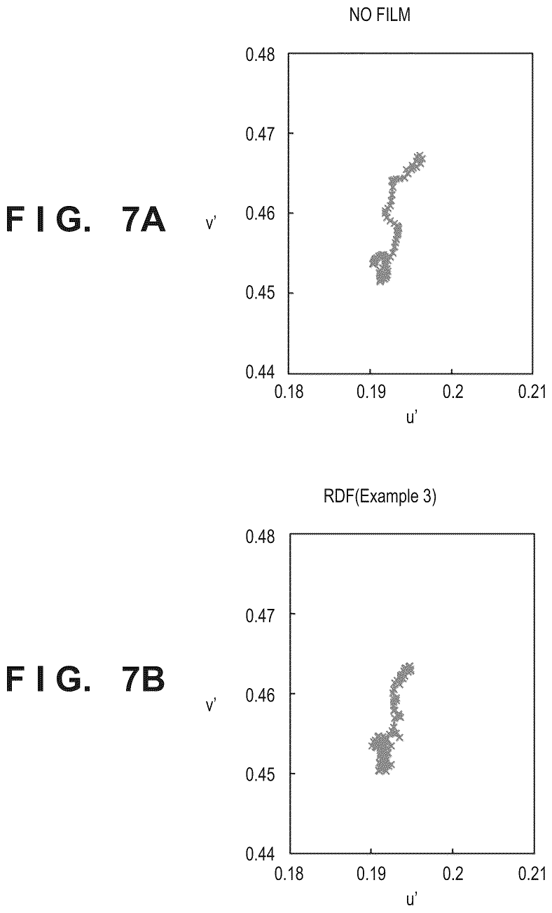

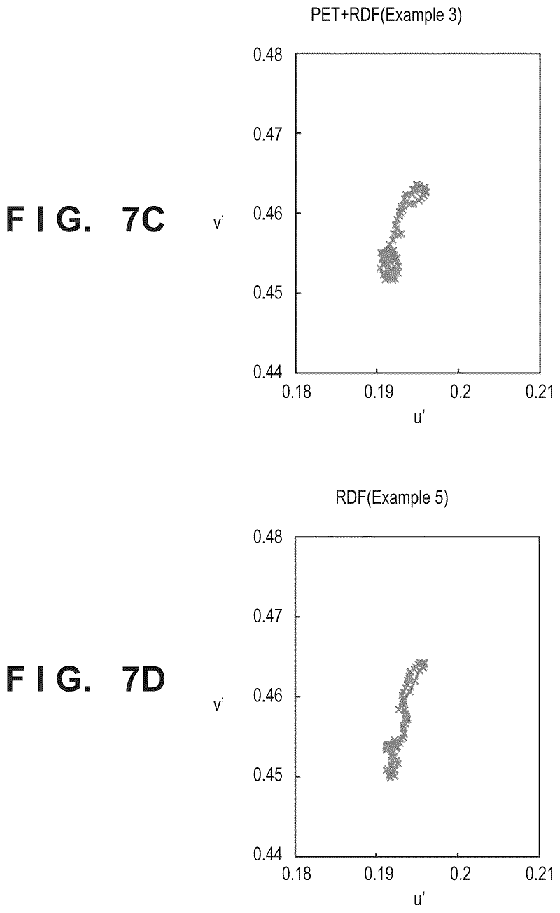

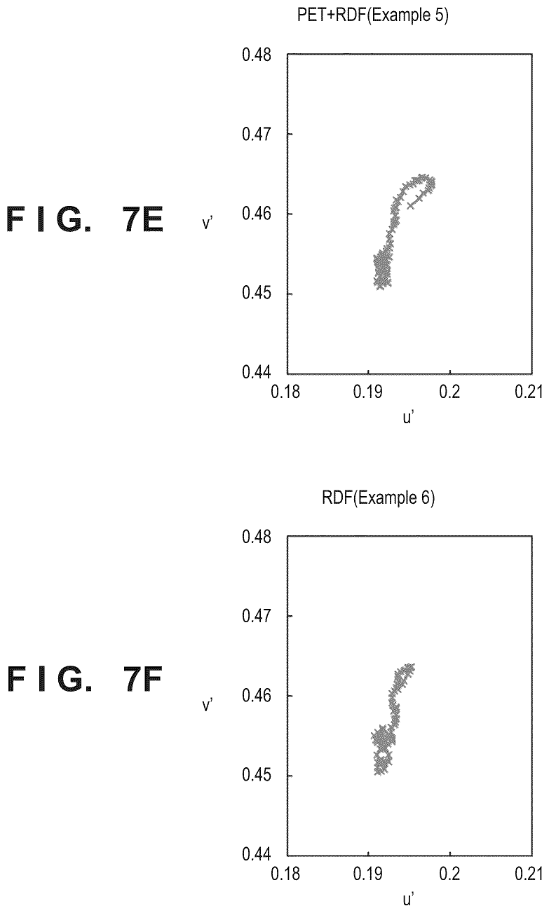

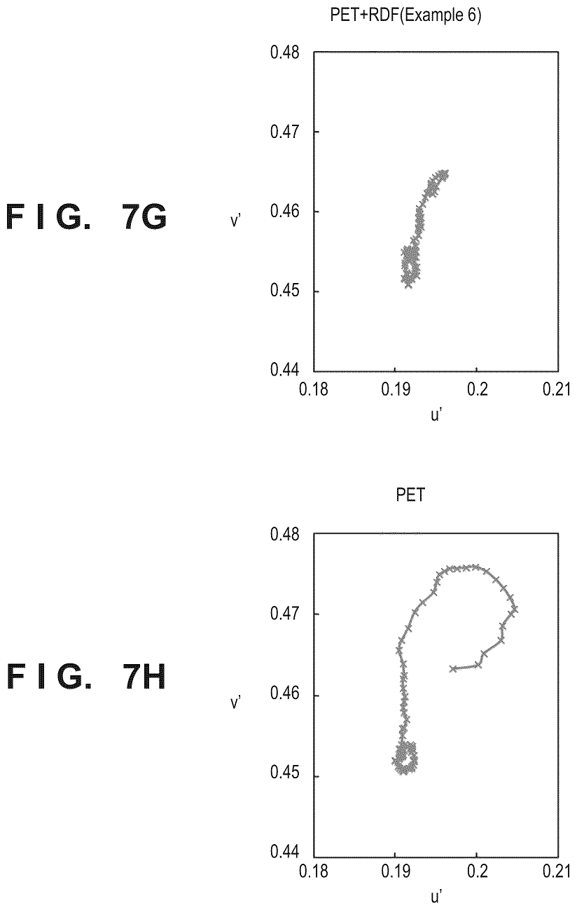

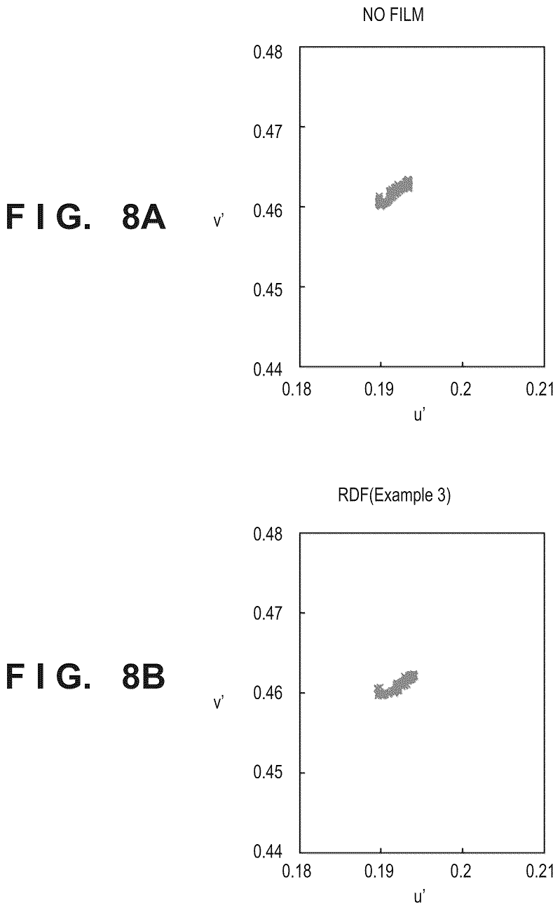

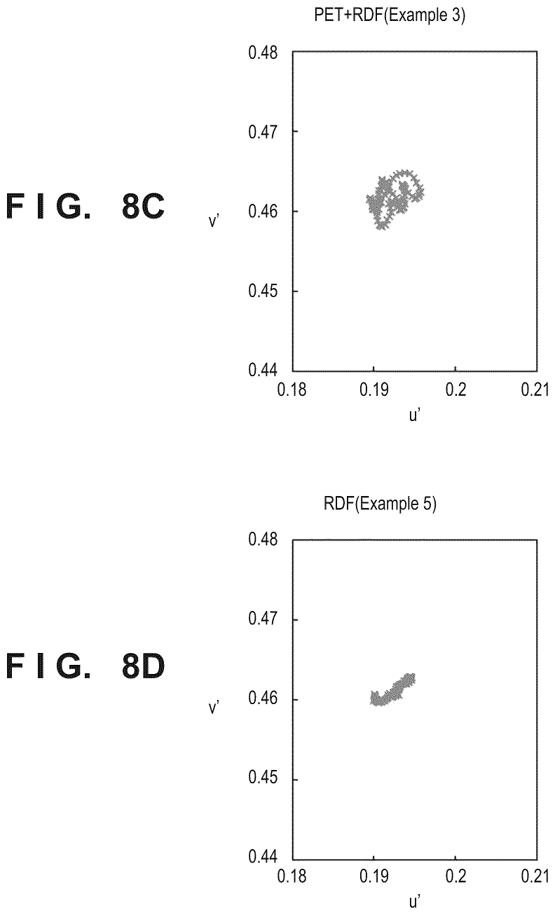

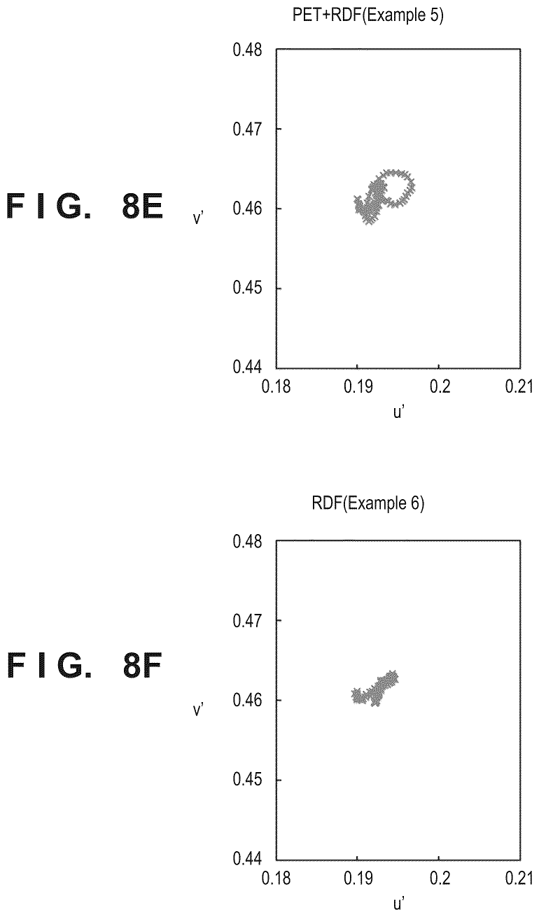

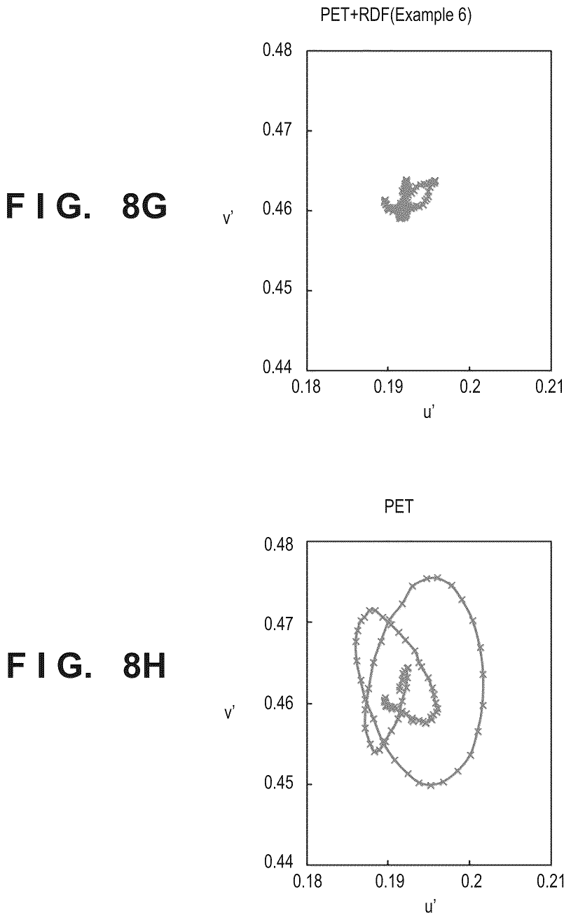

FIGS. 7A to 7H show the chromaticity measurement results of a reference example, Examples 3, 5, and 6, and Comparative Example 7 under measurement condition 1 (ϕ=65°, θ=0° to 80°). FIGS. 8A to 8H show the chromaticity measurement results of the reference example, Examples 3, 5, and 6, and Comparative Example 7 under measurement condition 2 (ϕ=65°, θ=0° to 90°). Here, the reference example indicates an LCD without an optical film and a PET film pasted. In Examples 3, 5, and 6, the chromaticity (u′, v′) was measured in measurement form 1 and measurement form 2. Measurement form 1 indicates a form in which only an RDF (indicating an optical film) is pasted to an LCD. Measurement form 2 indicates a form in which both a PET and an RDF (indicating an optical film) are pasted to an LCD.

Qualitative evaluation concerning a rainbow pattern on the LCD will be described with reference to FIGS. 7A to 7H and FIGS. 8A to 8H. It is found in advance that no rainbow pattern occurs on the LCD of the reference example shown in FIG. 7A. Since the existence range of the locus of the chromaticity (u′, v′) with respect to the v′ axis and the u′ axis in each of FIGS. 7B to 7G is substantially the same as the existence range of the locus of the chromaticity in FIG. 7A, no rainbow pattern occurs on the LCDs shown in FIGS. 7B to 7G. On the other hand, since the existence range of the locus of the chromaticity (u′, v′) in FIG. 7H is wider than the existence range of the locus of the chromaticity in FIG. 7A, a rainbow pattern occurs on the LCD shown in FIG. 7H.

Similarly, it is found in advance that no rainbow pattern occurs on the LCD of the reference example shown in FIG. 8A. Since the existence range of the locus of the chromaticity (u′, v′) with respect to the v′ axis and the u′ axis in each of FIGS. 8B to 8G is substantially the same as the existence range of the locus of the chromaticity in FIG. 8A, no rainbow pattern occurs on the LCDs shown in FIGS. 8B to 8G. On the other hand, since the existence range of the locus of the chromaticity (u′, v′) in FIG. 8H is wider than the existence range of the locus of the chromaticity in FIG. 8A, a rainbow pattern occurs on the LCD shown in FIG. 8H. Detailed evaluation results shown in FIGS. 7B to 7H and FIGS. 8B to 8H and in Test Example 7 based on the evaluation criteria are shown in Tables 7 and 8. As shown in Table 7, Examples 3, 5, and 6 had a remarkable effect of suppressing a rainbow pattern on the LCDs in both measurement form 1 and measurement form 2.

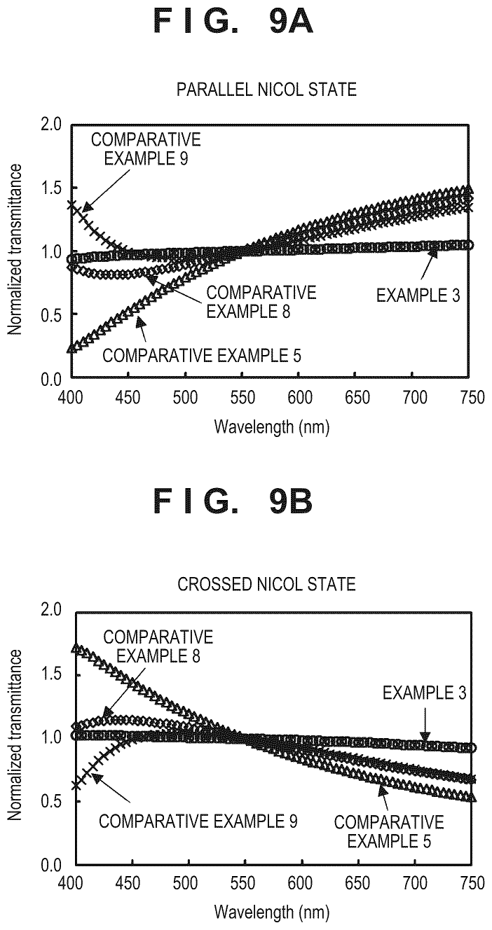

FIG. 9A is a view showing the wavelength dependence of transmittances of Example 3 and Comparative Examples 5, 8, and 9 in a parallel Nicol state. FIG. 9B is a view showing the wavelength dependence of transmittances of Example 3 and Comparative Examples 5, 8, and 9 in a crossed Nicol state. Referring to FIGS. 9A and 9B, in Example 3, the normalized transmittance took a value within the range of 90% to 110% at wavelengths of 400 to 750 nm. That is, in Example 3, since the wavelength dependence of the transmittance does not exist, a change of the color of an image can be suppressed in the visible light range. On the other hand, in each of Comparative Examples 5, 8, and 9, the normalized transmittance took a value outside the range of 90% to 110% at some of the wavelengths of 400 to 750 nm. That is, in Comparative Examples 5, 8, and 9, since the wavelength dependence of the transmittance exists, the color of an image changes at a specific wavelength at which the normalized transmittance is higher or lower than a predetermined value (90% to 110%) in the visible light range.

TABLE 7

| | | Ex- | Ex- | Ex- | Ex- | Ex- | Ex- | Ex- | Ex- | Ex- |
|---|---|---|---|---|---|---|---|---|---|---|
| | | ample | ample | ample | ample | ample | ample | ample | ample | ample |
| Test items | | 1 | 2 | 3 | 4 | 5 | 6 | 7 | 8 | 9 |
| thickness of optical | | 50 | 60 | 50 | 50 | 50 | 55 | 50 | 60 | 100 |
| film (μm) | | | | | | | | | | |
| depolarization | | present | present | present | present | present | present | present | present | present |
| degree of polarization | | 87 | 87 | 36 | 27 | 48 | 41 | 65 | 52 | 87 |
| (%) | | | | | | | | | | |
| haze (%) | | 20 | 8 | 25 | 31 | 31 | 34 | 36 | 32 | 8 |
| chromaticity change | | 0.01 | 0.02 | 0.01 | 0.01 | 0.02 | 0.02 | 0.03 | 0.03 | 0.01 |
| amount (maximum | | | | | | | | | | |
| value is employed) | | | | | | | | | | |
| clarity | | ◯ | ◯ | ⊚ | ⊚ | ⊚ | ⊚ | ◯ | ◯ | ◯ |
| contrast | contrast | 860 | 873 | 1068 | 1037 | 1020 | 1026 | 961 | 986 | 870 |
| | ratio | | | | | | | | | |
| | ratio of | 77 | 78 | 95 | 93 | 91 | 92 | 86 | 88 | 78 |
| | contrast | | | | | | | | | |
| | ratio (%) | | | | | | | | | |
| rainbow | without | — | — | ◯ | — | ◯ | ◯ | — | — | — |
| pattern | PET film | | | | | | | | | |
| evaluation | with PET | — | — | ◯ | — | ◯ | ◯ | — | — | — |
| | film | | | | | | | | | |
| wavelength dependence | | — | — | ◯ | | ◯ | ◯ | — | — | — |
| of transmittance | | | | | | | | | | |
| clarity at | without | — | — | ⊚ | — | ⊚ | ⊚ | — | — | — |
| large | polarizing | | | | | | | | | |
| pixel | plate | | | | | | | | | |
| pitch | crossed | — | — | ⊚ | — | ⊚ | ⊚ | — | — | — |
| | Nicol state | | | | | | | | | |
| clarity at | without | — | — | Δ | — | Δ | Δ | — | — | — |
| small | polarizing | | | | | | | | | |
| pixel | plate | | | | | | | | | |
| pitch | crossed | — | — | Δ | — | Δ | Δ | — | — | — |
| | Nicol state | | | | | | | | | |

* Explanatory Notes
Test item “without PET film” corresponds to measurement form 1.
Test item “with PET film” corresponds to measurement form 2.

TABLE 8

| | | Com- | Com- | Com- | Com- | Com- | Com- | Com- | Com- | Com- | Com- |
|---|---|---|---|---|---|---|---|---|---|---|---|
| | | parative | parative | parative | parative | parative | parative | parative | parative | parative | parative |
| | | Ex- | Ex- | Ex- | Ex- | Ex- | Ex- | Ex- | Ex- | Ex- | Ex- |
| | | ample | ample | ample | ample | ample | ample | ample | ample | ample | ample |
| Test items | | 1 | 2 | 3 | 4 | 5 | 6 | 7 | 8 | 9 | 10 |
| thickness of | | 50 | 55 | 65 | 60 | 70 | 50 | 12 | 56 | 75 | 42-62 |
| optical film (μm) | | | | | | | | | | | |
| depolarization | | present | present | present | present | present | present | — | present | present | present |
| degree of | | 87 | 82 | 84 | 83 | 0 | — | — | 5 | 3 | 64-83 |
| polarization (%) | | | | | | | | | | | |
| haze (%) | | 29 | 19 | 32 | 30 | 0.43 | 0.93 | — | 0.08 | 0.06 | 23-58 |
| chromaticity | | 0.05 | 0.04 | 0.01 | 0.05 | 0.12 | — | — | 0.05 | 0.02 | 0.011-0.048 |
| change | | | | | | | | | | | |
| amount | | | | | | | | | | | |
| (maximum | | | | | | | | | | | |
| value is | | | | | | | | | | | |
| employed) | | | | | | | | | | | |
| clarity | | X | X | X | X | ⊚ | ⊚ | — | ⊚ | ⊚ | X |
| con- | contrast | 565 | 809 | 765 | 782 | 1113 | — | — | 1164 | 1185 | 578-814 |
| trast | ratio | | | | | | | | | | |
| | ratio of | 50 | 72 | 68 | 70 | 99 | — | — | 104 | 106 | 52-73 |
| | contrast | | | | | | | | | | |
| | ratio (%) | | | | | | | | | | |
| rainbow pattern | | — | — | — | — | — | — | X | — | — | — |
| evaluation | | | | | | | | | | | |
| wavelength | | — | — | — | — | X | — | — | X | X | — |
| dependence of | | | | | | | | | | | |
| transmittance | | | | | | | | | | | |
| clarity | without | — | ⊚ | — | — | — | — | — | — | — | ⊚ |
| at | polarizing | | | | | | | | | | |
| large | plate | | | | | | | | | | |
| pixel | crossed | — | ◯ | — | — | — | — | — | — | — | ◯ |
| pitch | Nicol | | | | | | | | | | |
| | state | | | | | | | | | | |
| clarity | without | — | Δ | — | — | — | — | — | — | — | Δ |
| at | polarizing | | | | | | | | | | |
| small | plate | | | | | | | | | | |
| pixel | crossed | — | Δ | — | — | — | — | — | — | — | Δ |
| pitch | Nicol | | | | | | | | | | |
| | state | | | | | | | | | | |

The followings were found from the results shown in Tables 7 and 8. In particular, the optical characteristics (the degree of polarization, the haze, the chromaticity change amount, the clarity, and the contrast) of Example 3 were improved as compared to the optical characteristics of Comparative Examples 1 to 2 and 10 (calcite (calcium carbonate) was contained as an inorganic material). The optical characteristics (the rainbow pattern evaluation, the wavelength dependence of the transmittance, and the clarity by the pixel pitch difference) of Examples 3, 5, and 6 were more excellent than those of Comparative Examples 2 and 7 to 10.

Here, a supplementary explanation of the clarity by the pixel pitch difference in Examples 3, 5, and 6 will be made. The evaluation results of the clarity by the pixel pitch difference in Examples 3, 5, and 6 particularly exhibited a remarkable effect of improving the clarity of an image on the display with a large pixel pitch. Recently, large displays are used as digital signages (electronic signboards) in, for example, train stations, restaurants, supermarkets, shopping centers, drugstores, hospitals, hotels, banks, schools, offices, and everywhere else. In a conventional technique, however, since the clarity of images displayed on large displays installed in various places is insufficient, users may find it difficult to view the contents of the images. When the optical film according to the present invention is pasted to a large display, an image on the display screen is clear, and the visibility of the image to the user can be improved. Also, even if the resolution of a large display increases, like 4K or 8K, due to future technical innovations, the pixel pitch is expected not to be 100 μm×100 μm or less. As described above, since the present invention can increase the clarity of an image displayed on a large display, it is possible to implement rich visual presentation in various places in the future as compared to the conventional technique.

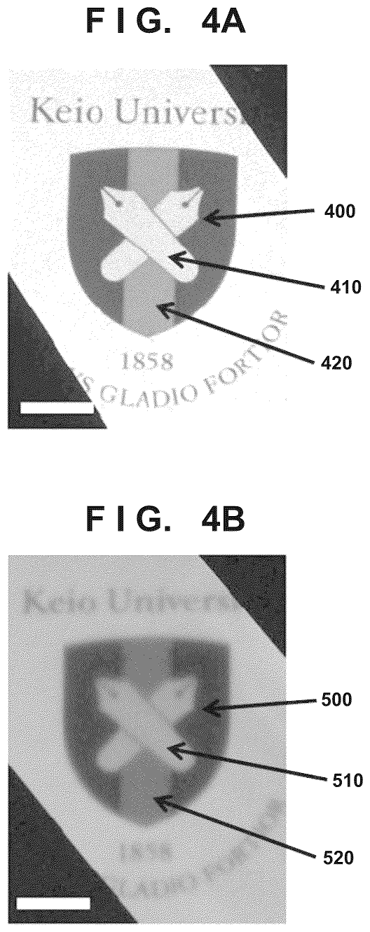

FIG. 4A is a view showing an image obtained by capturing, in a crossed Nicol state, an image of a display screen with the optical film of Example 3 pasted thereon. FIG. 4B is a view showing an image obtained by capturing, in a crossed Nicol state, an image of a display screen with the optical film of Comparative Example 1 pasted thereon. In FIG. 4A, for example, “Keio University” is clearly displayed, and a part 400 (blue), a part 410 (yellow), and a part 420 (red), which form the emblem of Keio University, are displayed in colors that should originally be displayed. On the other hand, In FIG. 4B, “Keio University” is unclearly displayed, and a part 500, a part 510, and a part 520, which form the emblem of Keio University, are displayed in colors less identifiable than in FIG. 4A. For example, the part 400 in FIG. 4A is displayed in blue, but the part 500 in FIG. 4B is displayed in black. As described above, if the optical film (Comparative Examples 1 and 2) containing calcite is used, the color of an image on the display screen changes to a color different from the color that should originally be displayed.

The optical characteristics (the degree of polarization, the haze, the clarity, and the contrast) of Example 3 were improved as compared to the optical characteristics of Comparative Examples 3 and 4 (PET was contained as a synthetic polymer material).

The optical characteristic (chromaticity change amount) of Example 3 was improved as compared to the optical characteristic of Comparative Examples 5, 8, and 9 (a ¼ retardation plate was used). Particularly, in Example 3, it is possible to suppress a change of the color of an image on the display screen when the user views the display device.

The optical characteristic (depolarization) of Example 1 was improved as compared to the optical characteristic of Comparative Example 6 (a natural fiber or the like was not contained). It was confirmed that if neither a natural fiber nor a non-natural fiber was contained in the translucent resin composition, a polarization state could not be obviously canceled.

As described above, the present invention has a remarkable effect of suppressing a change of the color of an image on the display screen when the user observes the display screen.

The invention is not limited to the foregoing embodiments, and various variations/changes are possible within the spirit of the invention.

1. A translucent resin composition comprising:
a transparent resin; and
a natural fiber having a birefringence Δn of 0.013 to 0.15 and an average particle size of 2 to 100 μm,
wherein the translucent resin composition contains 1 to 20 parts by mass of natural fiber with respect to 100 parts by mass of transparent resin,
wherein the translucent resin composition is used for depolarization,
wherein the natural fiber is an animal fiber,
wherein the average particle size is a particle diameter (D50: median diameter) corresponding to 50% in the volume-based cumulative particle size distribution measured by the laser diffraction method, and
wherein the birefringence Δn is determined based on a maximum retardation R, which corresponds to an interference color on a microregion of particle of the natural fiber observed in a crossed Nicol state using a polarizing microscope, and Δn=R/t (where t is the average particle size of the natural fiber).

2. A translucent resin composition comprising:
a transparent resin; and
a natural fiber having a maximum retardation of 300 to 1,300 nm and an average particle size of 2 to 100 μm,
wherein the translucent resin composition contains 1 to 20 parts by mass of natural fiber with respect to 100 parts by mass of transparent resin,
wherein the translucent resin composition is used for depolarization,
wherein the natural fiber is a silk,
wherein the average particle size is a particle diameter (D50: median diameter) corresponding to 50% in the volume-based cumulative particle size distribution measured by the laser diffraction method, and
wherein the maximum retardation is determined based on an interference color on a microregion of particle of the natural fiber observed in a crossed Nicol state using a polarizing microscope.

3. A translucent resin composition comprising:
a transparent resin; and
a natural fiber having a birefringence Δn of 0.013 to 0.15 and an average particle size of 2 to 100 μm,
wherein the translucent resin composition contains 1 to 20 parts by mass of natural fiber with respect to 100 parts by mass of transparent resin,
wherein the translucent resin composition is used for depolarization,
wherein the transparent resin is a fluororesin-free transparent resin,
wherein the natural fiber is not nanofiber,
wherein the average particle size is a particle diameter (D50: median diameter) corresponding to 50% in the volume-based cumulative particle size distribution measured by the laser diffraction method, and
wherein the birefringence Δn is determined based on a maximum retardation R, which corresponds to an interference color on a microregion of particle of the natural fiber observed in a crossed Nicol state using a polarizing microscope, and Δn=R/t (where t is the average particle size of the natural fiber).

4. The translucent resin composition according to claim 1, wherein
the transparent resin is a fluororesin-free transparent resin, and wherein the natural fiber is not a nanofiber.

5. The translucent resin composition according to claim 1, wherein the transparent resin is a transparent resin which does not include a fluororesin, a (meth)acrylic resin, and a thermosetting resin, and wherein the natural fiber is not a nanofiber.

6. The translucent resin composition according to claim 1, wherein the translucent resin composition is used for suppressing a rainbow pattern on a display screen of a display device.

7. The translucent resin composition according to claim 1, wherein the average particle size of the natural fiber is 3 to 25 μm.

8. The translucent resin composition according to claim 1, wherein the average particle size of the natural fiber is 4 to 20 μm, and wherein the translucent resin composition further contains an organic solvent (except polar solvent).

9. The translucent resin composition according to claim 1, wherein
the natural fiber is a silk.

10. The translucent resin composition according to claim 1, wherein the transparent resin (except a fluororesin) includes one of a vinyl resin, a polycondensation resin, a polyaddition resin, an addition-condensation resin, and a ring-opening polymerization resin.

11. The translucent resin composition according to claim 1, wherein the transparent resin includes one of a polyolefin resin, a vinyl chloride resin, a vinyl acetate resin, a (meth)acrylic resin, a polyester resin, a polysulfone resin, a polycarbonate resin, a amide resin, a polyimide resin, and a cyclic olefin resin.

12. The translucent resin composition according to claim 1, wherein the transparent resin is a polycarbonate resin.

13. An adhesive agent made of a translucent resin composition according to claim 1 and configured to adhere adherends.

14. An optical film that is a film made of a translucent resin composition according to claim 1.

15. A display device for emitting light in a polarization state, comprising:
at least one of an optical film and an adhesive agent arranged on an observer side of the display device,
wherein at least one of the optical film and the adhesive agent contains a translucent resin composition according to claim 1.
